(19) United States
(12) Patent Application Publication
(10) Pub. No.: US 2017/0354062 A1
(43) Pub. Date: Dec. 7, 2017

(54) HEAT PIPE ASSEMBLY AND HEAT PIPE STRUCTURE

(71) Applicant: Acer Incorporated, New Taipei City (TW)

(72) Inventors: Jian-Siang Wang, New Taipei City (TW); Hung-Chi Chen, New Taipei City (TW); Cheng-Yu Cheng, New Taipei City (TW)

(73) Assignee: Acer Incorporated, New Taipei City (TW)

(21) Appl. No.: 15/341,885

(22) Filed: Nov. 2, 2016

(30) Foreign Application Priority Data
Jun. 4, 2016 (TW) 105117706

(51) Int. Cl. H05K 7/20; F28F 9/013

(52) U.S. Cl. CPC H05K 7/20336; F28F 9/013; F28F 2275/20; F28F 2275/12

(57) ABSTRACT

A heat pipe assembly adapted to an electronic device is provided. The heat pipe assembly includes at least one heat pipe, a bracket, and at least one fixing member. The heat pipe is disposed in a body of the electronic device. The bracket is assembled to a portion of the heat pipe, and positions and suspends the heat pipe in the housing. The fixing member is fixed to the bracket by penetrating the housing from an exterior of the housing, such that the bracket and the housing are fixed to each other. A heat pipe structure is also provided.

### CROSS-REFERENCE TO RELATED APPLICATION

This application claims the priority benefit of Taiwan application serial no. 105117706, filed on Jun. 4, 2016. The entirety of the above-mentioned patent application is hereby incorporated by reference herein and made a part of this specification.

### BACKGROUND

### Technical Field

The disclosure relates to a heat pipe assembly and a heat pipe structure.

### Description of Related Art

Along with development of technology, current mobile electronic devices are all developed towards a trend of lightness, slimness, shortness and smallness, so that a problem of insufficient space is occurred due to the trend of compact in structural configuration.

For example, in order to achieve a required execution performance and a heat dissipation performance of a mobile electronic device, a designer often faces with the need to configure components required to achieve the aforementioned performances within a limited space, and meanwhile an overall structure has to be taken into consideration to avoid insufficient structural strength, which always causes a considerable trouble to the designer.

Therefore, how to provide a simple structure to make sure that the aforementioned components can all be properly configured in a housing of the mobile electronic device is an important issue considered by related technicians.

### SUMMARY

The disclosure is directed to a heat pipe assembly and a heat pipe structure, which are adapted to provide a better space configuration when being assembled in a housing of an electronic device.

The disclosure provides a heat pipe assembly adapted to an electronic device. The heat pipe assembly includes at least one heat pipe, a bracket, and at least one fixing member. The heat pipe is disposed in a housing of the electronic device. The bracket is assembled to a portion of the heat pipe, and positions and suspends the heat pipe in the housing. The fixing member is fixed to the bracket by penetrating through the housing from an exterior of the housing, such that the bracket and the housing are fixed to each other.

The disclosure provides a heat pipe structure including a heat pipe and a bracket. A portion of the heat pipe is combined with the bracket to produce a deformation, and the deformed portion is closely fit to a part of a contour of the bracket.

According to the above description, in the heat pipe assembly, through collaboration of the bracket and the fixing member, after the bracket is assembled to a portion of the heat pipe, the bracket is fixed to the housing through the fixing member, such that the bracket and the portion of the heat pipe are positioned and suspended in the housing, where besides that the fixing member and the heat pipe are not interfered with each other due to the bracket, the bracket may also provide a positioning and fixing effect to the heat pipe.

Moreover, a portion of the heat pipe is combined with the bracket to produce a deformation, and the deformed portion is closely fit to a part of a contour of the bracket. In this way, during a manufacturing process of the heat pipe, manufacturing of the bracket is completed at the same time, such that the heat pipe can be easily fixed to a required position, and thus an assembly procedure is accordingly simplified.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a partial schematic diagram of an electronic device according to an embodiment of the disclosure.

FIG. 2 is a partial cross-sectional view of the electronic device of FIG. 1.

FIG. 3 is a partial cross-sectional view of a heat pipe assembly according to another embodiment of the disclosure.

FIG. 4 and FIG. 5 are cross-sectional views of a heat pipe structure according to an embodiment of the disclosure.

FIG. 6 and FIG. 7 are cross-sectional views of a heat pipe structure according to an embodiment of the disclosure.

### DESCRIPTION OF EMBODIMENTS

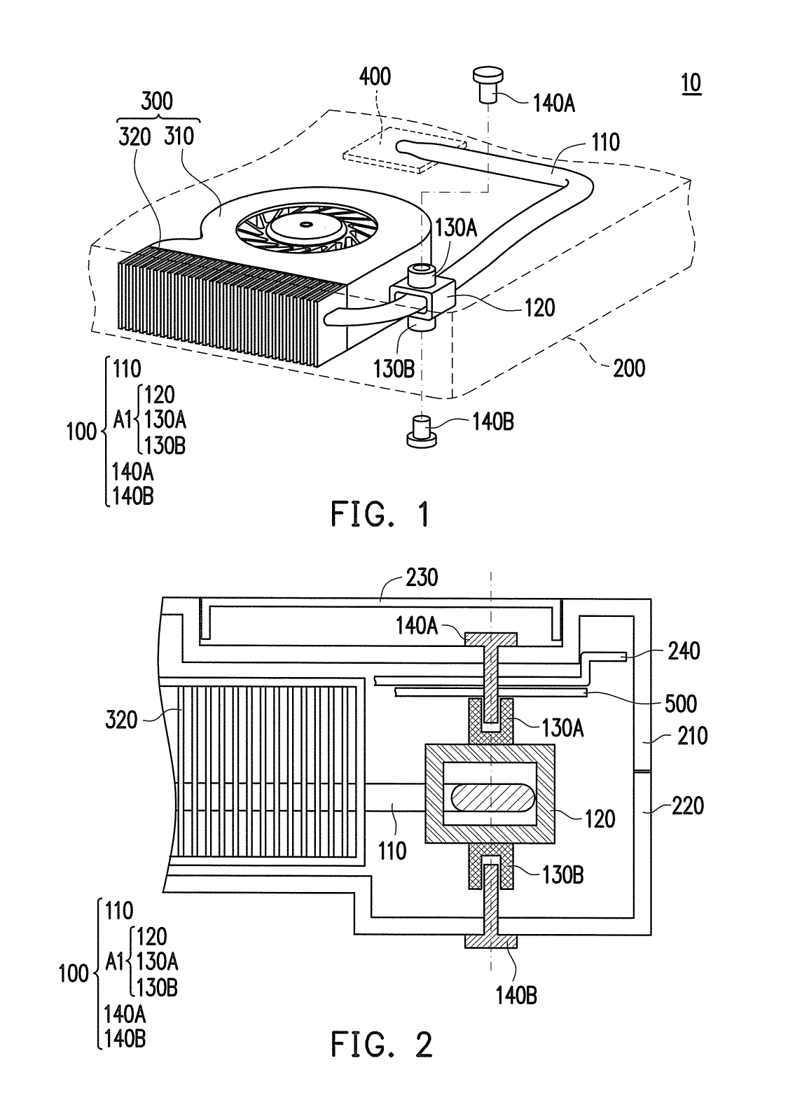

FIG. 1 is a partial schematic diagram of an electronic device according to an embodiment of the disclosure. FIG. 2 is a partial cross-sectional view of the electronic device of FIG. 1. Referring to FIG. 1 and FIG. 2, in the present embodiment, the electronic device 10 is, for example, a notebook computer, which includes a heat pipe assembly 100, a housing 200, a heat dissipation assembly 300 and a heat source 400, wherein the heat source 400 is, for example, a central processor or a display chip of the notebook computer. The heat dissipation assembly 300 includes a fan 310 and cooling fins 320, and the heat pipe assembly 100 includes a heat pipe 110, a bracket A1 and fixing members 140A and 140B.

The heat source 400 contacts one end of the heat pipe 110, and another end of the heat pipe 110 is connected to the cooling fins 320 by penetrating through the same, and through a phase transformation of a working fluid (e.g. the working fluid in liquid is transformed to vapor by absorbing heat, or the working fluid in vapor is transformed to liquid by dissipating heat, which are not shown here) in the heat pipe 110, heat generated by the heat source 400 is conducted to the cooling fins 320 through the heat pipe 110, and the fan 310 runs to dissipate the heat of the cooling fins 320 to achieve an effect of dissipating the heat generated by the heat source 400 to the outside of the housing 200 of the electronic device 10.

As described above, under the limited space of the housing 200, how to balance the structural strength of the electronic device 10 and the component configuration within the housing 200 is an important issue required to be considered.

In the present embodiment, the bracket A1 includes a main body 120, and standoffs 130A, 130B, where the main body 120 is a sleeve member, which sleeves a portion of the heat pipe 110, and the standoffs 130A, 130B are respectively disposed on two opposite surfaces of the main body 120, and respectively extend towards an upper casing 210 and a lower casing 220 of the housing 200. Here, the standoffs 130A, 130B are, for example, screw hole columns, and the fixing members 140A, 140B are, for example, screws. Therefore, the fixing members 140A and 140B may respectively penetrate through the upper casing 210 and the lower casing 220 of the housing 200 for being locked to the standoffs 130A, 130B, such that the main body 120 and the heat pipe 110 passing there through can be positioned and suspended in the housing 200 (i.e. between the upper casing 210 and the lower casing 220). In this way, not only the whole structure of the electronic device 10 may achieve a required strength due to the locking effect implemented by the standoffs 130A, 130B and the fixing members 140A, 140B, but also the heat pipe 110 may pass through the fixing members 140A, 140B without being influenced, which avails a space configuration within the housing 200. In other words, a portion of the heat pipe 110 combined with the bracket A1 is substantially located on an axial direction (for example, a center line shown in FIG. 2) along which the fixing member 140A or 140B is fixed to the bracket A1, and the portion of the heat pipe 110 is not interfered with the fixing member 140A or 140B.

In the present embodiment, although two fixing members 140A, 140B and two standoffs 130A, 130B are illustrated, the disclosure is not limited thereto, and in another embodiment that is not illustrated, under the premise of satisfying the structural strength, only one fixing member and one standoff can be adopted to fix the bracket and the housing.

Referring to FIG. 2, in the present embodiment, the upper casing 210 is, for example, a casing structure of a palmrest in a host of the notebook computer, and the lower casing 220 is, for example, a bottom casing structure used for leaning against a platform in the host of the notebook computer. Therefore, the fixing member 140B substantially penetrates through the lower casing 220 upward from the bottom of the housing 200 and is fixed to the standoff 130B of the bracket A1, and the fixing member 140A penetrates through the upper casing 210, a hinge bracket 240 and a mainboard 500 downward from the top of the housing 200 and is fixed to the standoff 130A of the bracket A1. Meanwhile, considering the upper casing 210 is substantially a main appearance member of the housing 200, a cover 230 can be assembled to the upper casing 210 to shield the fixing member 140A. Here, the cover 230 can be a cover used for covering a hard disk of the notebook computer, which is not limited by the disclosure.

Moreover, in the present embodiment, the main body 120 of the bracket A1 and the heat pipe 110 can be mutually positioned and fixed through spot welding. In this way, the bracket A1 may also serve as a heat dissipation structure of the heat pipe 110, so as to increase a heat dissipation area to improve a heat dissipation effect of the heat pipe 110.

On the other hand, the main body 120 of the bracket A1 and the standoffs 130A, 130B can be an integral structure, or the standoffs 130A, 130B can be assembled to or welded to the main body 120, which is not limited by the disclosure.

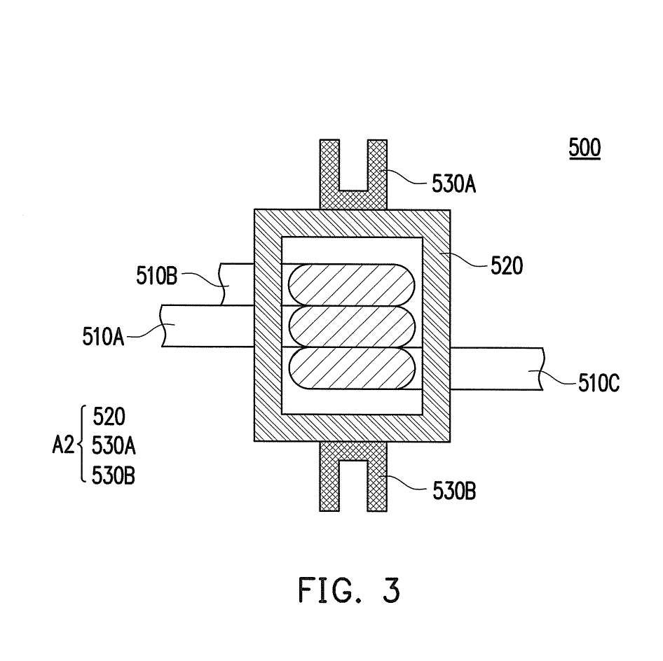

FIG. 3 is a partial cross-sectional view of the heat pipe assembly according to another embodiment of the disclosure. Referring to FIG. 3, different to the aforementioned embodiment, the heat pipe assembly 500 of the present embodiment includes a plurality of heat pipes 510A, 510B and 510C, so that a height of a hollow contour of a main body 520 of a bracket A2 can be correspondingly changed according to a thickness of the overlapped heat pipes 510A, 510B and 510C, and standoffs 530A, 530B are the same to the standoffs of the aforementioned embodiment, so as to achieve the same fixing effect as that of the aforementioned embodiment.

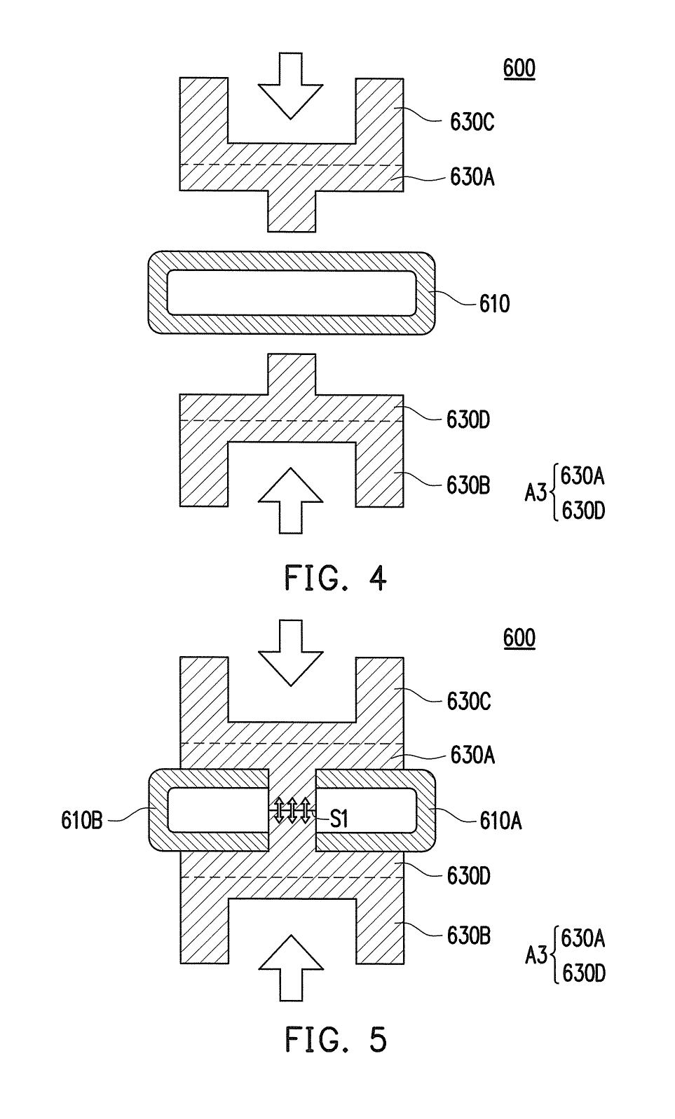

FIG. 4 and FIG. 5 are cross-sectional views of a heat pipe structure according to an embodiment of the disclosure, which are used for describing a forming process of the heat pipe structure. Referring to FIG. 4 and FIG. 5, in the present embodiment, the heat pipe structure 600 includes a heat pipe 610 and a bracket, where the bracket can still be divided into a main body A3 and a first standoff 630C, a second standoff 630B, where the main body A3 and the heat pipe 610 are mutually combined. However, before the assembling, the main body A3 substantially includes a first contact portion 630A and a second contact portion 630D separated from each other, and the first standoff 630C and the first contact portion 630A are an integral structure, and the second standoff 630B and the second contact portion 630B are an integral structure.

Then, referring to FIG. 5, the first contact portion 630A and the second contact portion 630D are driven to penetrate through a portion of the heat pipe 610 to lean against to each other (which are closely combined at a contact surface S1 to serve as a main body A3 of the bracket), and the portion of the heat pipe 610 is accordingly deformed, and the deformed portion is closely fit to a part of contours of the first contact portion 630A and the second contact portion 630D, such that the portion of the heat pipe 610 is separated into two portions 610A and 610B, and the working fluid therein can be maintained to normally flow and does not leak out from the portion.

In other words, in the present embodiment, the structure of the bracket is completed during a manufacturing process of the heat pipe 610, and the heat pipe 610, the main body A3 of the bracket and the standoffs 630B, 630 form an integral structure, such that the heat pipe structure 600 is adapted to be fixed on any object, for example, on the housing 200 of the aforementioned embodiment, so as to simplify a follow-up procedure for assembling the electronic device.

More importantly, when the fixing members (shown as the aforementioned embodiment, which are omitted in the present embodiment) are respectively fixed to the standoffs 630B, 630C to fix the bracket and objects (for example, the upper casing 210 and the lower casing 220 of the aforementioned embodiment) of the present embodiment as that does in the aforementioned embodiment, since the first contact portion 630a and the second contact portion 630D may lean against each other at the contact surface S1 (shown by double arrow symbols at the contact surface S1 of FIG. 5), a fixing (locking) force of the fixing members can be freely transferred through the contact surface S1 without being obstructed by the heat pipe 610, so as to provide a better combining force to improve the structural strength.

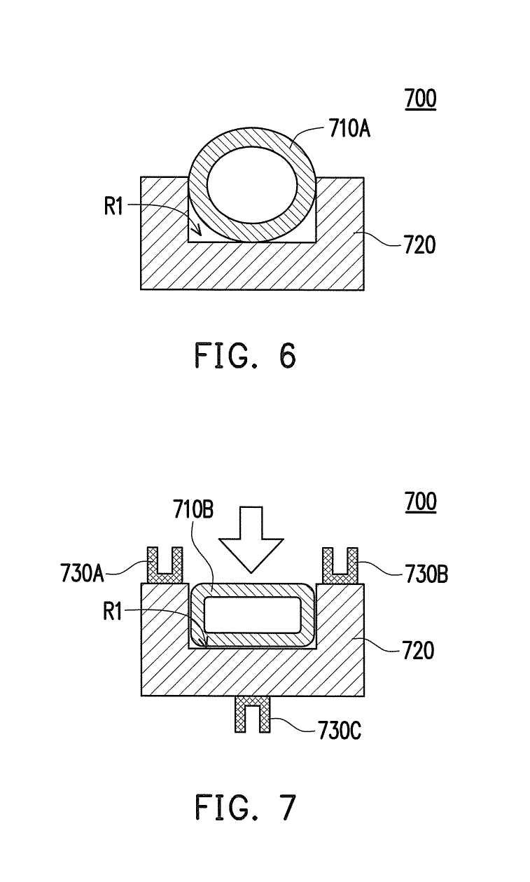

FIG. 6 and FIG. 7 are cross-sectional views of a heat pipe structure according to an embodiment of the disclosure, which are used for describing a forming process of the heat pipe structure. Referring to FIG. 6 and FIG. 7, the present embodiment is similar to the aforementioned embodiment, the heat pipe structure 700 of the present embodiment also includes a heat pipe and a bracket, though the heat pipe is substantially combined with the bracket through a squeezing manner. As shown in FIG. 6, a main body 720 of the bracket has a recess R1, and the heat pipe 710A before shaping is disposed in the recess R1, and then a squeezing force (shown by an arrow of FIG. 7) is exerted to squeeze and shape the heat pipe 710 in the recess R1, and meanwhile the main body 720 and the heat pipe 710A can be stably combined together. The deformed heat pipe 710B is substantially fit to a contour of the recess R1 closely. Moreover, standoffs 730A, 730B and 730C are configured on the main body 720 as that does of the aforementioned embodiment to complete the heat pipe structure 700. Similarly, the bracket and the heat pipe can be manufactured together, so as to effectively decrease a time required for assembling the electronic device, and the quantity of the standoffs 730A, 730B and 730C and positions thereof on the main body 720 are not limited by the embodiment.

In summary, in the aforementioned embodiments of the disclosure, through collaboration of the bracket and the fixing members of the heat pipe assembly, after the bracket is assembled to a portion of the heat pipe, the bracket is fixed to the housing through the fixing members, such that the bracket and the portion of the heat pipe are positioned and suspended in the housing, where besides that the fixing member and the heat pipe are not interfered with each other due to the bracket, the bracket may also provide a positioning and fixing effect to the heat pipe.

Moreover, a portion of the heat pipe is combined with the bracket to produce a deformation, and the deformed portion is closely fit to a part of a contour of the bracket. In this way, during a manufacturing process of the heat pipe, manufacturing of the bracket is completed at the same time, such that the heat pipe can be easily fixed to a required position, and thus an assembly procedure is accordingly simplified.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A heat pipe assembly, adapted to an electronic device, the heat pipe assembly comprising:
at least one heat pipe, disposed in a housing of the electronic device;
a bracket, assembled to a portion of the heat pipe, and positioning and suspending the heat pipe in the housing; and
at least one fixing member, fixed to the bracket by penetrating through the housing from an exterior of the housing, such that the bracket and the housing are fixed to each other.

2. The heat pipe assembly as claimed in claim 1, wherein the bracket comprises:
a main body, assembled to the portion of the heat pipe; and
at least one standoff, configured on at least one side of the main body facing the housing, wherein the at least one fixing member is fixed to the at least one standoff by penetrating through the housing from the exterior of the housing, such that the main body and the heat pipe are supported by the standoff and suspended in the housing.

3. The heat pipe assembly as claimed in claim 2, wherein the main body is a sleeve member sleeving the portion of the heat pipe.

4. The heat pipe assembly as claimed in claim 2, wherein the main body and the standoff are an integral structure.

5. The heat pipe assembly as claimed in claim 2, wherein the main body and the heat pipe are an integral structure.

6. The heat pipe assembly as claimed in claim 2, wherein the main body has a first contact portion and a second contact portion respectively penetrating through two opposite sides of a cross section of the heat pipe for leaning against to each other, the at least one standoff comprises a first standoff and a second standoff, and the first standoff and the first contact portion are an integral structure, and the second standoff and the second contact portion are an integral structure.

7. The heat pipe assembly as claimed in claim 2, wherein the main body has a recess, and the portion of the heat pipe is squeezed in the recess.

8. The heat pipe assembly as claimed in claim 2, wherein the housing comprises an upper casing and a lower casing assembled to each other, the at least one standoff comprises a plurality of standoffs respectively disposed on the main body facing the upper casing and on the main body facing the lower casing, the at least one fixing member comprises a plurality of fixing members respectively penetrating through the upper casing, the lower casing for being correspondingly fixed to the standoffs.

9. The heat pipe assembly as claimed in claim 1, wherein the portion of the heat pipe is located on an axial direction along which the fixing member is fixed to the bracket, and the portion of the heat pipe and the fixing member are not interfered with each other.

10. A heat pipe structure, comprising:
a heat pipe; and
a bracket, a portion of the heat pipe is combined with the bracket to produce a deformation, and the deformed portion is closely fit to a part of a contour of the bracket.

11. The heat pipe structure as claimed in claim 10, wherein the bracket comprises:
a main body, wherein the portion of the heat pipe is combined to the main body and deformed, and the deformed portion is fit to a contour of the main body; and
at least one standoff, configured on at least one side of the main body, wherein the main body and the heat pipe are fixed to an object through the at least one standoff.

12. The heat pipe structure as claimed in claim 11, wherein the main body and the at least one standoff are an integral structure.

13. The heat pipe structure as claimed in claim 11, wherein the main body has a first contact portion and a second contact portion respectively penetrating through two opposite sides of the portion of the heat pipe for leaning against to each other, and the portion of the heat pipe is closely fit to a contour of the first contact portion and a contour of the second contact portion.

14. The heat pipe structure as claimed in claim 13, wherein the at least one standoff comprises a first standoff and a second standoff, and the first standoff and the first contact portion are an integral structure, and the second standoff and the second contact portion are an integral structure.

15. The heat pipe structure as claimed in claim 11, wherein the main body has a recess, and the portion of the heat pipe is squeezed in the recess, such that the portion is fit a contour of the recess.
